(19) United States
(12) Patent Application Publication
(10) Pub. No.: US 2010/0001722 A1
(43) Pub. Date: Jan. 7, 2010

(54) MAGNETIC SENSOR DEVICE WITH SUPPRESSION OF SPURIOUS SIGNAL COMPONENTS

(75) Inventors: Josephus Arnoldus Henricus Maria Kahlman, Tilburg (NL); Bart Michiel De Boer, Den Bosch (NL); Theodorus Petrus Henricus Gerardus Jansen, Deurne (NL); Jeroen Veen, Nijmegen (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/518,890

(22) PCT Filed: Dec. 12, 2007
(86) PCT No.: PCT/IB2007/055057

§ 371 Date: Jun. 12, 2009

(30) Foreign Application Priority Data
Dec. 18, 2006 (EP) 06126394.3

(51) Int. Cl. G01R 33/02

(52) U.S. Cl. 324/228; 324/244

(57) ABSTRACT

The invention relates to a magnetic sensor device for the determination of magnetized particles (3) which comprises a magnetic field generator (1, 1′)(e.g. a conductor wire) that is driven with an excitation current (I₁) of a first frequency (f₁), and a magnetic sensor element (2) (e.g. a GMR resistance), that is driven with a sensor current (I₂) of a second frequency (f₂) for generating measurement signals (U_{GMR}). A preprocessed signal (uf) is then generated from the measurement signal (U_{GMR}) that comprises a predetermined frequency (Δf), and an evaluation unit (10) separates from this preprocessed signal a spurious component that does not depend on the presence of magnetized particles (3) in the sample chamber. The spurious component (U_{Q}) may particularly be caused by self-magnetization (H₂) of the magnetic sensor element (2) in combination with parasitic (capacitive or inductive) cross-talk. Furthermore, an unknown, variable phase-shift (φ_{SP}) in the preprocessed signal (u_{f}) may be determined by varying the ratio between the spurious component and a particle-dependent target component. This variation may for example be achieved if, in an optimization stage (OS), the excitation current (I₁) is conducted through a bypass resistor (R, R′) and/or if an additional capacitor is introduced between the magnetic field generator and the magnetic sensor element. The determined phase shift can then be used to adjust the phase of a demodulation signal (u_{dem}) such that the spurious component is suppressed.

The invention relates to a method and a magnetic sensor device for detecting magnetized particles in a sample chamber. Moreover, it relates to the use of such a device.

From the WO 2005/010543 A1 and WO 2005/010542 A2 a magnetic sensor device is known which may for example be used in a microfluidic biosensor for the detection of (e.g. biological) molecules labeled with magnetic beads. The microsensor device is provided with an array of sensor units comprising wires for the generation of a magnetic field and Giant Magneto Resistance devices (GMRs) for the detection of stray fields generated by magnetized beads. The resistance of the GMRs is then indicative of the number of the beads near the sensor unit.

A problem with biosensors of the aforementioned kind is that the measurement signals comprise components that are not related to the presence of magnetized particles and therefore impair the accuracy of the measurement results.

Based on this situation it was an object of the present invention to provide means for improving the accuracy of measurements with magnetic sensor devices.

This object is achieved by a magnetic sensor device according to claim 1, a method according to claim 2, and a use according to claim 12. Preferred embodiments are disclosed in the dependent claims.

The magnetic sensor device according to the present invention serves for the detection of magnetized particles, for example of magnetic beads that label target molecules in a sample. It comprises the following components:
A sample chamber in which the particles to be detected can be provided. The sample chamber is typically an empty cavity or a cavity filled with some substance like a gel that may absorb a sample; it may be an open cavity, a closed cavity, or a cavity connected to other cavities by fluid connection channels.
At least one magnetic field generator that is driven with an excitation current comprising a first frequency for generating a magnetic excitation field (at least somewhere) in the sample chamber. Saying that “a signal comprises some frequency” shall here and in the following be a short expression for the fact that the Fourier spectrum of said signal is non-zero for said frequency. The magnetic field generator may particularly be realized by at least one conductor wire on the substrate of a microelectronic sensor.
At least one associated magnetic sensor element that is driven with a sensor current comprising a second frequency for generating a measurement signal. The magnetic sensor element is associated with the aforementioned magnetic field generator in the sense that it is in the reach of effects caused by the magnetic excitation field of said generator. The magnetic sensor element may particularly comprise coils, Hall sensors, planar Hall sensors, flux gate sensors, SQUIDS (Superconducting Quantum Interference Devices), magnetic resonance sensors, magneto-restrictive sensors, or magneto-resistive sensors of the kind described in the WO 2005/010543 A1 or WO 2005/010542 A2, especially a GMR, a TMR (Tunnel Magneto Resistance), or an AMR (Anisotropic Magneto Resistance).

The excitation current as well as the sensor current are typically provided by some power supply unit, for example a constant current source.
A signal processing circuit for generating a preprocessed signal from the measurement signal that comprises at least one predetermined frequency. The signal processing circuit will typically comprise one or more band-pass filters or demodulation means for implementing said functionality that select certain frequencies from the whole spectrum of the measurement signal, wherein said selected frequencies relate to the first and the second frequency. By such a frequency filtering, a lot of disturbances that are not related to the presence of magnetic particles can be sorted out. Moreover, the signal processing circuit typically comprises an amplifier.
An evaluation unit for separating from the preprocessed signal at least one “spurious component” that by definition does not depend on the presence of magnetized particles in the sample chamber. The evaluation unit may be realized by dedicated hardware and/or by some microcomputer system together with appropriate software. It is preferably coupled by wire to the magnetic sensor element for receiving the measurement signals. The “separation” of the spurious component from the measurement signal may particularly mean that it is suppressed by the evaluation unit, so that the output of the evaluation unit is the measurement signal without the spurious component. Separation may however also mean that the spurious component is isolated or determined and used for further purposes.

The described magnetic sensor device achieves a high correlation of its output with the amount of magnetized particles in the sample chamber, i.e. the value of interest, by (i) using first and second frequencies for the excitation and sensor current, respectively, (ii) selecting from the spectrum of the measurement signal a preprocessed signal with predetermined frequencies, and (iii) separating in the preprocessed signal a spurious component that is not related to the presence of magnetized particles. Particularly the last processing step provides an additional improvement of the accuracy as it addresses the fact that a selection of certain frequency bands may not be sufficient to isolate particle-related components of the measurement signal from particle-unrelated disturbances.

The invention further comprises a method for the determination of particles in a sample chamber with the help of a magnetic sensor device (particularly the device described above), wherein the method comprises the following steps:
Generating a magnetic excitation field in the sample chamber with a magnetic field generator that is driven with an excitation current comprising a first frequency.
Generating a measurement signal with a magnetic sensor element that is driven with a sensor current comprising a second frequency.
Generating a preprocessed signal from the measurement signal with a signal processing circuit, wherein said preprocessed signal comprises at least one predetermined frequency.
Separating with an evaluation unit a spurious component from the preprocessed signal that does not depend on the presence of magnetized particles in the sample chamber.

The method comprises in general form the steps that can be executed with a magnetic sensor device of the kind described above. Therefore, reference is made to the preceding description for more information on the details, advantages and improvements of that method.

In the following, preferred embodiments of the invention are described that relate both to the proposed magnetic sensor device and the method.

Thus the predetermined frequency that is comprised in the preprocessed signal may particularly be the difference between the first frequency of the excitation current and the second frequency of the sensor current (if said currents comprise several such first and second frequencies, a corresponding number of frequency differences may be used as predetermined frequencies). As an analysis shows, the difference between the first and the second frequency relates to a component of the measurement signal that reflects the presence of magnetized particles in the sample chamber.

For certain concrete designs of the magnetic sensor device, the composition of the preprocessed signal can be analyzed and attributed to particular physical effects. In one such case, the preprocessed signal comprises a “target component” that is due to magnetic reaction fields of particles in the sample chamber which are excited by the magnetic excitation field; moreover, the preprocessed signal comprises a spurious component that has the same frequency as said target component but a definite phase-shift with respect to it. Such a phase-shift is typically introduced by certain physical effects or by the presence of certain electrical components in the magnetic sensor device. The phase-shift may particularly have a value of about 90°, which allows to cancel the spurious component by demodulating the measurement signal with a demodulation signal that is in phase with the target component.

In another particular embodiment of the invention, which is preferably realized in combination with the aforementioned one, the spurious component is generated by the self-magnetization of the magnetic sensor element in combination with capacitive and/or inductive parasitic cross-talk between the magnetic field generator and the magnetic sensor element. As the self-magnetization is related to the second frequency (of the sensor current) and as the parasitic cross-talk is related to the first frequency (of the excitation current), these two effects generate a spurious component of the measurement signal having the same frequency as a particle-dependent target component that is produced by a combination of magnetic reaction fields (first frequency) and sensor current (second frequency). Such a spurious component can therefore not be suppressed by a simple frequency filtering but requires a more elaborate treatment in the evaluation unit. As will be explained in more detail with reference to the Figures, this treatment may be based on the (fixed) phase-shift that is present between the spurious and the target component.

It was already mentioned that the separation/suppression of the spurious component may readily be achieved by a proper demodulation signal if there is a fixed phase difference between it and a target component one is interested in. In practice, this simple approach is however impeded by the fact that the preprocessed signal may comprise a variable, unknown phase-shift (in the component with the predetermined frequency). Such a variable phase-shift may for example be due to temperature effects, aging, production tolerances of electronic components and the like. It makes the use of a simple demodulation signal with a fixed phase practically useless as it is not known in which ratio this demodulation signal comprises the target signal and the spurious component, respectively.

In order to deal with the aforementioned situation, the evaluation unit may optionally comprise a phase-estimator for determining the variable phase-shift that is present in the preprocessed signal. Knowledge of the actual value of the variable phase-shift may then for example be used to adjust a demodulation signal accordingly.

In a further development of the invention, the magnetic sensor device comprises a reference circuit that can selectively be activated by the evaluation unit for varying the relative magnitude of the spurious component. The resulting variation in the ratio between the spurious component and a target component of the preprocessed signal can be exploited by the evaluation unit to determine individually these components from their superposition, i.e. from the preprocessed signal. Moreover, this approach implicitly provides information about a possible phase-shift introduced by the signal processing circuit.

In one particular embodiment of the aforementioned approach, the reference circuit comprises a bypass resistor through which the excitation current can bypass the magnetic field generator if the reference circuit is activated. The resulting removal of the excitation current from the magnetic field generator ceases the generation of magnetic excitation fields and therefore zeroes the particle-dependent target components of the preprocessed signal, which obviously allows to determine the spurious component.

In another embodiment, the reference circuit comprises a capacitor that couples the magnetic field generator and the magnetic sensor element. The capacitor therefore introduces an artificial capacitive coupling which amplifies a spurious component that is due or similar to such a capacitive coupling.

In still another embodiment, the reference circuit comprises at least one additional magnetic field generator for generating a magnetic cross-talk field that can be detected by the magnetic sensor element. When the magnetic cross-talk field is present, an artificial magnetic cross-talk component is introduced which is in phase with a corresponding target component, thus reducing the relative magnitude of the associated spurious component.

The invention further relates to the use of the magnetic sensor device described above for molecular diagnostics, biological sample analysis, and/or chemical sample analysis, particularly the detection of small molecules. Molecular diagnostics may for example be accomplished with the help of magnetic beads that are directly or indirectly attached to target molecules.

These and other aspects of the invention will be apparent from and elucidated with reference to the embodiment(s) described hereinafter. These embodiments will be described by way of example with the help of the accompanying drawings in which:

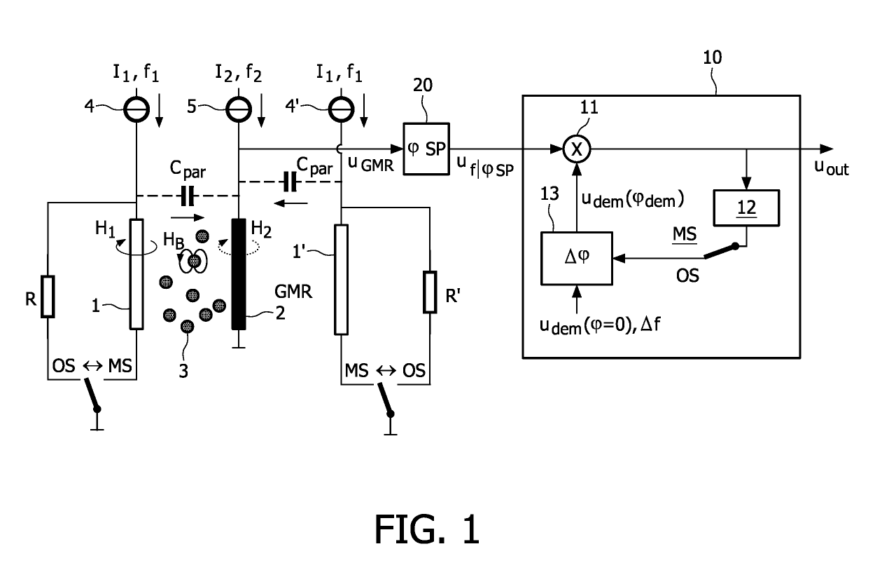

FIG. 1 shows a schematic circuit diagram of a magnetic sensor device which comprises bypass-resistors according to a first embodiment of the present invention;

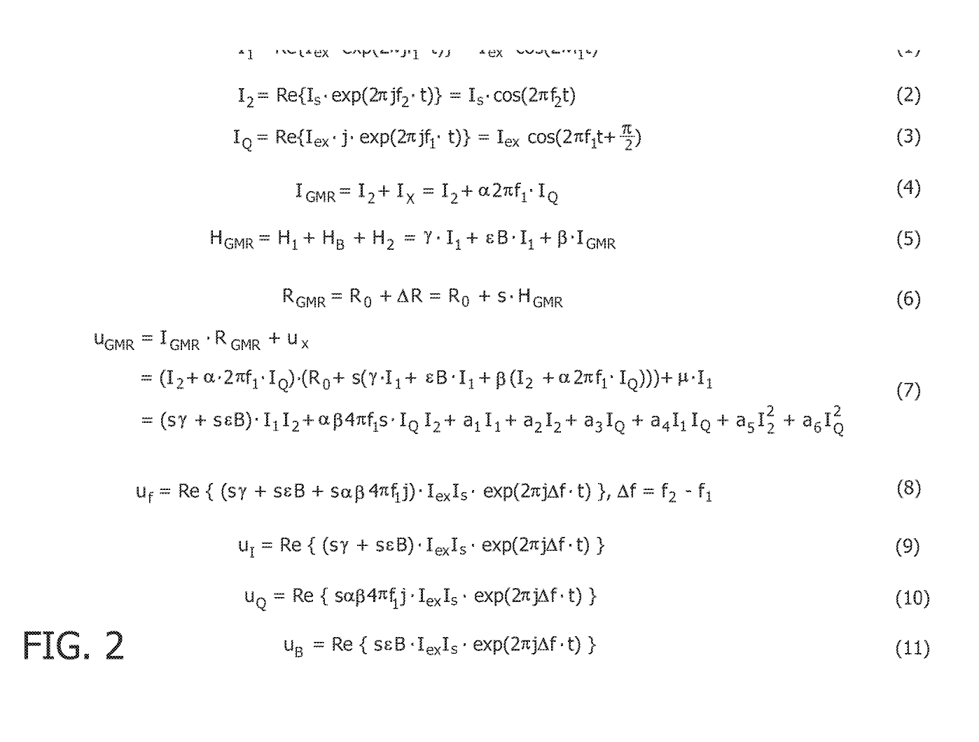

FIG. 2 summarizes mathematical expressions related to the signal processing approach of the present invention;

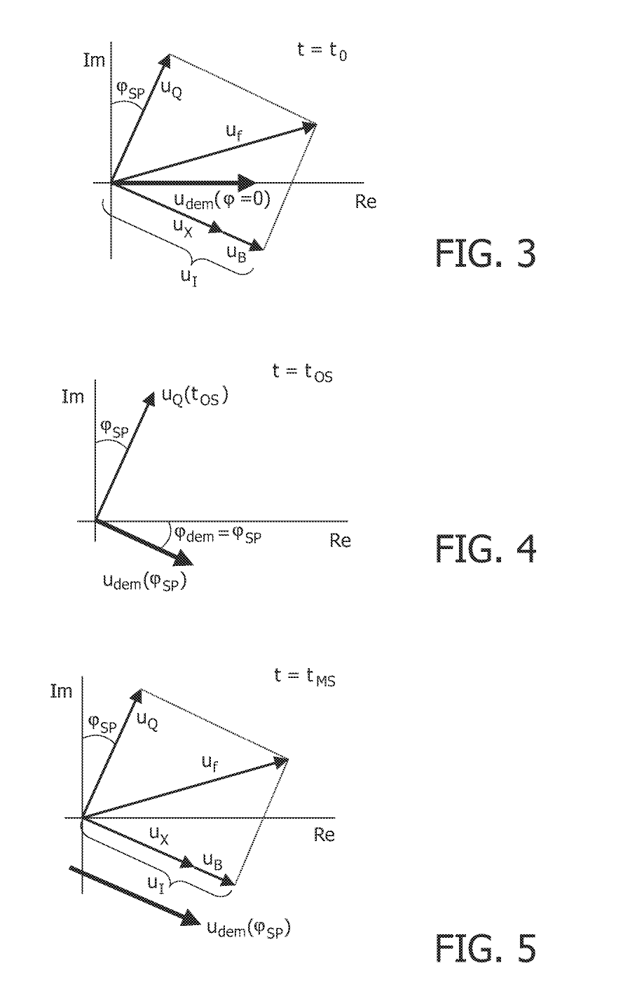

FIGS. 3 to 5 illustrate the components of a preprocessed measurement signal at Δf in the complex plane, wherein FIG. 3 shows the situation before an optimization stage, FIG. 4 shows the determination of the phase-shift during an optimization stage in which the target component is zero, and FIG. 5 shows the next measurement stage after the demodulation signal has been adapted;

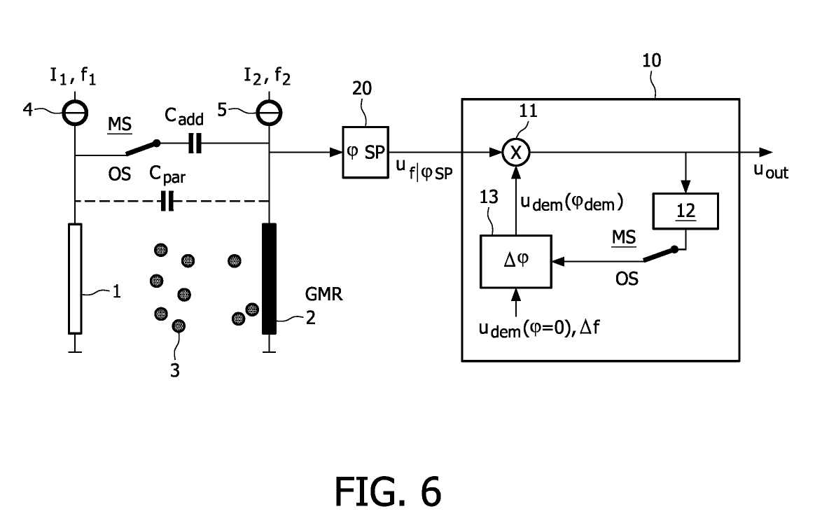

FIG. 6 shows a schematic circuit diagram of a magnetic sensor device which comprises an additional capacitor according to a second embodiment of the present invention;

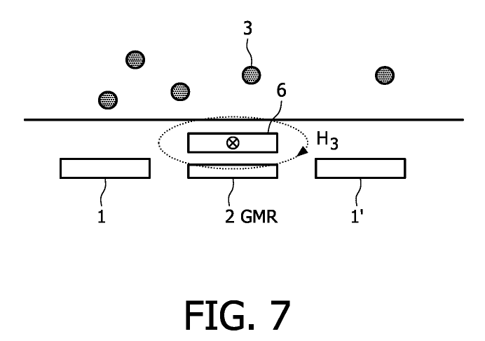

FIG. 7 shows a schematic cross section through a magnetic sensor device which comprises a cross-talk generating wire according to a third embodiment of the present invention.

Like reference numbers in the Figures refer to identical or similar components.

FIG. 1 illustrates a microelectronic magnetic sensor device according to the present invention in the particular application as a biosensor for the detection of magnetically interactive particles, e.g. superparamagnetic beads 3, in a sample chamber. Magneto-resistive biochips or biosensors have promising properties for bio-molecular diagnostics, in terms of sensitivity, specificity, integration, ease of use, and costs. Examples of such biochips are described in the WO 2003/054566, WO 2003/054523, WO 2005/010542 A2, WO 2005/010543 A1, and WO 2005/038911 A1, which are incorporated into the present application by reference.

The magnetic sensor device shown in FIG. 1 comprises at least one magnetic field generator which may be realized as a conductor wire 1 on a substrate (not shown) or which may be located outside the sensor chip. The field generator 1 is driven by a current source 4 with a sinusoidal excitation current I₁ of a first frequency f₁ for generating an alternating external magnetic field H₁ in an adjacent sample chamber. The excitation current I₁ is expressed in equation (1) of FIG. 2 with the help of a complex representation and a (constant, real) amplitude Iₑₓ. FIG. 1 further shows a second magnetic excitation wire 1′ driven by a second current source 4′ to illustrate that the design can readily be extended to a multi-wire situation.

The generated magnetic excitation field H₁ magnetizes beads 3 in the sample chamber, wherein said beads 3 may for instance be used as labels for (bio-)molecules of interest (for more details see cited literature). Magnetic reaction fields H_{B} generated by the beads 3 then affect (together with the excitation field H₁) the electrical resistance of a nearby Giant Magneto Resistance (GMR) sensor element 2.

For measuring the magnetic reaction field H_{B}, a sinusoidal sensor current I₂ of frequency f₂ is generated by a further current source 5 and conducted through the GMR sensor element 2. This sensor current I₂ is expressed in equation (2) in a complex representation and with a (constant, real) amplitude Iₛ.

The voltage u_{GMR} that can be measured across the GMR sensor 2 then provides a sensor signal indicative of the resistance of the GMR sensor 2 and thus of the magnetic fields it is subjected to.

FIG. 1 further indicates by capacitors Cₚₐᵣ and dashed lines a parasitic capacitive coupling between the excitation wires 1, 1′ and the GMR sensor 2. This capacitive coupling and/or an additional inductive coupling between the excitation wires 1, 1′ and the GMR sensor 2 induces a cross-talk component uₓ of the measurement voltage u_{GMR} and an associated additional cross-talk current I_{X} through the GMR sensor 2. The cross-talk current I_{X} is proportional to the excitation current I₁, but phase shifted by 90°. The cross-talk current I_{X} and the sensor current I₂ together yield the total current I_{GMR} through the GMR sensor 2. The corresponding mathematical description of the mentioned currents is given in equations (3) and (4), wherein α is a constant.

FIG. 1 further shows that the total current I_{GMR} induces a self-magnetization with a field H₂ acting on the GMR sensor 2. Equation (5) summarizes the total magnetic field H_{GMR} the GMR sensor 2 is exposed to, wherein β, γ, and ε are constants and B is the bead density on the surface of the sensor that is looked for (assuming a uniform distribution of beads on the surface).

Equation (6) expresses the total resistance of the GMR sensor 2, R_{GMR}, as the sum of a constant (ohmic) term R₀ and a variable term ΔR that depends via the sensor gain s on the total magnetic field H_{GMR} prevailing in the GMR element 2.

Equation (7) gives the measurement signal u_{GMR} that is generated by the GMR sensor 2 and processed by a signal processing circuit 20 (FIG. 1), wherein μ, a₁, a₂, a₃, a₄, a₅, a₆ are constants. This measurement signal u_{GMR} is composed of the (ohmic) voltage drop across the GMR sensor 2 and the additional cross-talk voltage u_{X} mentioned above. As can be seen from equation (7), the measurement signal u_{GMR} comprises several components which are proportional to different products of the excitation current I₁, the sensor current I₂ and the “quadrature current” I_{Q} defined in equation (3). Using equations (1)-(3) and trigonometric identities, it can be shown that these components correspond to particular frequencies. In particular, the products I₁·I₂ and I_{Q}·I₂ consist of frequency components at the difference frequency Δf=(f₁-f₂) and at (f₁+f₂) which appear in no other product. By an appropriate processing of the measurement signal u_{GMR} in the signal processing circuit 20, e.g. by passing it through a band-pass filter (after amplification in an amplifier) centered at the difference frequency Δf, the preprocessed or filtered signal u_{f} according to equation (8) is obtained. The difference frequency Δf is chosen such that the thermal noise of the GMR sensor 2 dominates the 1/f noise introduced by amplification. In order to produce the quantity of interest, namely the amplitude variation of the signal u_{f} at Δf, which is a measure for the amount of beads on the sensor, the signal u_{f} is demodulated in a demodulator 11 of an evaluation unit 10 using a demodulation signal u_{dem}(φ=0) of the difference frequency Δf that is in phase with the information signal. After demodulation, the output signal uₒᵤₜ of the evaluation unit 10 may e.g. be low-pass filtered and optionally be further processed.

FIG. 3 illustrates in the complex plane (Re, Im) a typical preprocessed signal u_{f} as it is provided to the evaluation unit 10 at some time t₀. According to equation (8), this preprocessed signal u_{f} comprises the following components:

1. The spurious or “quadrature-component” or shortly “Q-component” u_{Q}: As was explained above, capacitive and inductive cross-talk (inherent to the sensor geometry) give rise to a cross-talk current I_{X} through the GMR sensor with a frequency equal to the excitation frequency f₁. Furthermore, the applied sensor current I₂ gives rise to an internal magnetic field H₂ in the GMR sensor (self-biasing) at the second frequency f₂. Their product results in the Q-component u_{Q} at the difference frequency Δf, of which the phase is 90 degrees shifted with respect to the information carrying signal. According to equation (8), the amplitude of this Q-component u_{Q} is |u_{Q}|=2πf₁αβsIₑₓIₛ, where α is the quotient I_{c}/I₁ of cross-talk current (I_{c}) and applied excitation current (I₁), β is the self biasing factor H₂/I_{GMR}, i.e. the magnetic field strength H₂ in the sensitive layer of the GMR sensor induced by a current I_{GMR} through the GMR, and s=ΔR/ΔH is the sensitivity of the GMR sensor.

2. The magnetic cross-talk vector u_{X}: The (inherent) misalignment of excitation wires 1, 1′ and GMR sensor wires 2 results in a GMR response u_{X} to the magnetic field H₁ induced by the excitation current I₁. According to equation (9), |uₓ|=γsIₑₓIₛ where γ=H₂/I₁ is the proportionality constant between the magnetic field strength in the sensitive layer of the GMR induced by a current through the excitation wire and that current.

3. The “bead vector” u_{B}, which is caused by the beads and therefore represents the information carrying signal (“target signal”). u_{B} is given in equations (9) and (11), with ε=H_{B}/(BIₑₓ) being the proportionality constant between the magnetic field strength in the sensitive layer of the GMR induced by magnetized beads at the sensor surface and B being the bead density on the surface of the sensor.

4. The total magnetic vector or “I-component” u_{I}=u_{X}+u_{B} which comprises the aforementioned magnetic cross-talk u_{X} and the bead vector u_{B}.

FIG. 3 and equation (8) show that the preprocessed, filtered signal u_{f} has a spurious, particle-independent component u_{Q}. As this spurious component is orthogonal to the in-phase component u_{B} one is interested in, it can theoretically be suppressed by using a modulation signal u_{dem} that is in phase with the desired information carrying signal u_{B} (or u_{I}). The problem is however that the preprocessing electronics 20 introduces an unknown and time-variable phase-shift φ_{SP} which makes it impossible to simply select a fixed modulation signal u_{dem} that is in phase with the information signal. Using for example the out-of-phase demodulation signal u_{dem}(0) shown in FIG. 3 will yield measurement results that comprise disturbances of unknown size from the spurious component u_{Q}. The phase-shift φ_{SP} may vary due to for example production tolerances, aging effects or temperature variations. Moreover, φ_{SP} may be frequency depended due to analogue filtering or delays in digital processing (sampling).

In view of the aforementioned considerations, it is desirable to optimize the demodulation phase φ_{dem} of the demodulation signal u_{dem} in order to suppress the spurious component u_{Q}. This should be achieved in a robust and accurate adaptation algorithm for the demodulation phase φ_{dem} without complicated signal processing requirements and adaptable in analogue and digital demodulation implementations. As the phase shift φ_{SP} is time variant, repetitive adaptation is required.

In a general solution to the aforementioned situation, the amplitude relation between the parasitic crosstalk and the magnetic excitation field in the GMR sensor 12 is changed during an optimization stage OS. This will reveal the actual phase-shift φ_{SP}, and the demodulation phase φ_{dem} can then be optimized accordingly towards a maximal suppression of the spurious component u_{Q}. As the frequency during the optimization stage OS is the same as during the measurement stage MS, a high accuracy is achieved because frequency depended phase shifts (in the signal processing electronics) are avoided.

According to a first particular realization of the aforementioned general solution, the excitation current is made zero during an optimization stage OS. In the embodiment of FIG. 1, the excitation current I₁ is particularly removed from the excitation wires 1, 1′ and rerouted to dummy resistances R, R′ of a resistance value equal to that of the excitation wires 1, 1′ (e.g. 10 Ohm) in order to keep the impedance level for the current sources 4 and 4′ constant. This is especially needed when said current sources are followed by analog filter components (not shown), which responses are sensitive to the impedance level. As a result, the GMR signal u_{GMR} and therefore the preprocessed signal u_{f} only comprise the unwanted spurious component u_{Q}. The demodulation phase φ_{dem} can then be adapted to a value φ_{dem}=φ_{SP} such that the spurious component u_{Q} is maximally suppressed in the demodulated output signal uₒᵤₜ. According to FIG. 1, this can be achieved by controlling a programmable phase shifter 13 via a feedback loop 12 until uₒᵤₜ=0 during the optimization stage.

FIG. 4 shows the vector diagram corresponding to the optimization stage OS after the demodulation phase has been adjusted.

FIG. 5 shows the subsequent measurement stage MS, in which the excitation wires are again supplied with the excitation current I₁. As the phase of the demodulation signal u_{dem} is now adjusted, the spurious component u_{Q} is optimally suppressed.

It should be noted that the described optimization is based on a capacitive coupling (and not on an inductive coupling) when the resistors R, R′ are not closely located to the excitation wires 1, 1′. This however does not influence the end-result, as the phases of the capacitive and the inductive cross-talk currents are both orthogonal to the desired magnetic signal. The found demodulation phase φ_{dem} therefore also optimally suppresses spurious components due to inductive cross-talk.

The purpose of the resistors R, R′ (acting as a dummy excitation wires) is to maintain the phase of the excitation current I₁ in the optimization and the measurement stages. This is especially important when said excitation current I₁ is generated via a complex impedance, e.g. a higher order (low-pass) filter which makes the phase of the excitation current very sensitive to load impedance changes.

In a second embodiment of a magnetic sensor device shown in FIG. 6, the parasitic (capacitive, inductive) coupling is increased, preferably made largely dominant, with respect to the magnetic signal. This is achieved by adding extra coupling elements during an optimization stage OS, e.g. by adding a capacitor C_{add} between the excitation wire 1 and the GMR sensor 2. Analogous to the embodiment of FIG. 1, the demodulation phase φ_{dem} is optimized during an optimization stage OS towards a situation of uₒᵤₜ=0, so that the quadrature component u_{Q} is maximally suppressed. During the following measurement stage MS, this demodulation phase is then used to detect the magnetic signal.

This approach is extremely useful when the magnetic signal is small, e.g. when the magnetic cross-talk is suppressed by vertically aligning the excitation wire(s) and the GMR sensor.

In an alternative embodiment, the parasitic coupling (capacitive, inductive) is increased during an optimization stage, but not necessarily made dominant. As a result two responses appear, from which the optimal demodulation phase may be derived.

A third embodiment of a magnetic sensor device is shown in FIG. 7 in a schematic cross section during the optimization stage OS. This embodiment comprises an additional “cross-talk wire” 6 running out of the sensitive plane of the GMR sensor 2 (for example as shown parallel above the GMR sensor 2). The magnetic “cross-talk field” H₃ that is generated when this cross-talk wire 6 is supplied with the excitation current I₁ during the optimization stage OS then generates a strong magnetic cross-talk signal in the GMR sensor 2. Thus the magnetic cross-talk is substantially increased, preferably made largely dominant, with respect to the quadrature component u_{Q}. The latter can substantially be kept constant if the capacitive (and inductive) cross-talk between the GMR sensor 2 and the current wires 1, 1′, 6 is changed as little as possible. This if for example achieved if the additional cross-talk wire 6 has a similar distance from the GMR sensor 2 as the excitation wires 1, 1′ and if no excitation current is supplied to the excitation wires 1, 1′ during the optimization stage OS. The demodulation phase φ_{dem} can be optimized during the optimization stage OS towards a situation of “uₒᵤₜ=maximal”, so that the quadrature component u_{Q} will be maximally suppressed during the following measurement stage MS.

While the invention was described above with reference to particular embodiments, various modifications and extensions are possible, for example:
In addition to molecular assays, also larger moieties can be detected with magnetic sensor devices according to the invention, e.g. cells, viruses, or fractions of cells or viruses, tissue extract, etc.
The detection can occur with or without scanning of the sensor element with respect to the biosensor surface.
Measurement data can be derived as an end-point measurement, as well as by recording signals kinetically or intermittently.
The magnetic particles serving as labels can be detected directly by the sensing method. As well, the particles can be further processed prior to detection. An example of further processing is that materials are added or that the (bio)chemical or physical properties of the label are modified to facilitate detection.
The device and method can be used with several biochemical assay types, e.g. binding/unbinding assay, sandwich assay, competition assay, displacement assay, enzymatic assay, etc.
The device and method are suited for sensor multiplexing (i.e. the parallel use of different sensors and sensor surfaces), label multiplexing (i.e. the parallel use of different types of labels) and chamber multiplexing (i.e. the parallel use of different reaction chambers).
The device and method can be used as rapid, robust, and easy to use point-of-care biosensors for small sample volumes. The reaction chamber can be a disposable item to be used with a compact reader, containing the one or more magnetic field generating means and one or more detection means. Also, the device, methods and systems of the present invention can be used in automated high-throughput testing. In this case, the reaction chamber is e.g. a well plate or cuvette, fitting into an automated instrument.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A magnetic sensor device for detecting magnetized particles (3), comprising
a sample chamber in which the magnetized particles (3) can be provided;
at least one magnetic field generator (1, 1′) that is driven with an excitation current (I₁) comprising a first frequency (f₁) for generating a magnetic excitation field (H₁) in the sample chamber;
at least one associated magnetic sensor element (2) that is driven with a sensor current (I₂) comprising a second frequency (f₂) for generating a measurement signal (u_{GMR});
a signal processing circuit (20) for generating a preprocessed signal (u_{f}) from the measurement signal (u_{GMR}) that comprises a predetermined frequency (Δf);
an evaluation unit (10) for separating from the preprocessed signal (u_{f}) a spurious component (u_{Q}) that does not depend on the presence of magnetized particles (3) in the sample chamber.

2. A method for the determination of magnetized particles (3) in a sample chamber with the help of a magnetic sensor device, comprising the following steps:
generating a magnetic excitation field (H₁) and the sample chamber with a magnetic field generator (1, 1′) that is driven with an excitation current (I₁) comprising a first frequency (f₁);
generating a measurement signal (u_{GMR}) with a magnetic sensor element (2) that is driven with a sensor current (I₂) comprising a second frequency (f₂);
generating a preprocessed signal (u_{f}) from the measurement signal (u_{GMR}) with a signal processing circuit (20), wherein said preprocessed signal comprises a predetermined frequency (Δf);
separating with an evaluation unit (10) a spurious component (u_{Q}) from the preprocessed signal (u_{f}) that does not depend on the presence of magnetized particles (3) in the sample chamber.

3. The magnetic sensor device according to claim 1, characterized in that the predetermined frequency (Δf) is the difference between the first frequency (f₁) and the second frequency (f₂).

4. The magnetic sensor device according to claim 1, characterized in that the preprocessed signal (u_{f}) comprises a target component (u_{B}) that is generated by magnetic reaction fields (H_{B}) of particles (3) in the sample chamber which were magnetized by the magnetic excitation fields (H₁), and that the spurious component (u_{Q}) has the same frequency (Δf) but a phase-shift, particularly of 90°, with respect to the target component.

5. The magnetic sensor device according to claim 1, characterized in that the spurious component (u_{Q}) is generated by a self-magnetization (H₂) of the magnetic sensor element (2) in combination with capacitive and/or inductive cross-talk between the magnetic field generator (1, 1′) and the magnetic sensor element (2).

6. The magnetic sensor device according to claim 1, characterized in that the preprocessed signal (u_{f}) comprises a variable phase-shift (φ_{SP}).

7. The magnetic sensor device or the method according to claim 6, characterized in that the evaluation unit (10) comprises a phase estimator (12, 13) for determining said variable phase-shift (φ_{SP}).

8. The magnetic sensor device according to claim 1, characterized in that the magnetic sensor device comprises a reference circuit (6, R, R′, C_{add}) that can selectively be activated by the evaluation unit (10) for varying the relative magnitude of the spurious component (u_{Q}).

9. The magnetic sensor device or the method according to claim 8, characterized in that the reference circuit comprises a bypass-resistor (R, R′) via which the excitation current (I₁) can bypass the magnetic field generator (1, 1′).

10. The magnetic sensor device or the method according to claim 8, characterized in that the reference circuit comprises a capacitor (C_{add}) that couples the magnetic field generator (1, 1′) and the magnetic sensor element (2).

11. The magnetic sensor device or the method according to claim 8, characterized in that the reference circuit comprises at least one additional magnetic field generator (6) for generating a magnetic cross-talk field (H₃) that can be detected by the magnetic sensor element (2).

12. The magnetic sensor device according to claim 1, characterized in that the magnetic sensor element comprises a coil, a Hall sensor, a planar Hall sensor, a flux gate sensor, a SQUID, a magnetic resonance sensor, a magneto-restrictive sensor, or a magneto-resistive sensor like a GMR (2), an AMR, or a TMR element.

13. Use of the magnetic sensor device according to claim 1 for molecular diagnostics, biological sample analysis, and/or chemical sample analysis, particularly the detection of small molecules.
